(19) United States
(12) Patent Application Publication
(10) Pub. No.: US 2025/0338538 A1
(43) Pub. Date: Oct. 30, 2025

(54) Semiconductor Device with Hollow Chambers

(71) Applicant: Huawei Digital Power Technologies Co., Ltd., Shenzhen (CN)

(72) Inventor: Gilberto Curatola, Nuremberg (DE)

(73) Assignee: Huawei Digital Power Technologies Co., Ltd., Shenzhen (CN)

(21) Appl. No.: 19/259,864

(22) Filed: Jul. 3, 2025

Related U.S. Application Data
(63) Continuation of application No. PCT/EP2023/050976, filed on Jan. 17, 2023.

(51) Int. Cl. H10D 30/47; H10D 30/01; H10D 62/10; H10D 62/85

(52) U.S. Cl. CPC H10D 30/475; H10D 30/015; H10D 62/115; H10D 62/8503

(57) ABSTRACT

A semiconductor device includes a semiconductor substrate, an Aluminum Gallium-Nitride (AlGaN) back-barrier layer formed above the semiconductor substrate, and a GaN channel layer formed on the AlGaN back-barrier layer. A two-dimensional hole gas (2DHG) is formed at an interface between the GaN channel layer and the AlGaN back-barrier layer, and a p-type doped region is formed above the semiconductor substrate and next to the GaN channel layer and the AlGaN back-barrier layer. The p-type doped region is configured to provide an ohmic contact for the 2DHG. The p-type doped region comprises Magnesium as a p-type dopant. The p-type doped region comprises one or more hollow chambers extending from the top face of the p-type doped region. The hollow chambers are configured to form an escape path for Hydrogen atoms which are formed during a dopant activation of the p-type doped region during fabrication of the semiconductor device.

### CROSS-REFERENCE TO RELATED APPLICATIONS

This application is a continuation of International Application No. PCT/EP2023/050976, filed on Jan. 17, 2023, the disclosure of which is hereby incorporated by reference in its entirety.

### TECHNICAL FIELD

The disclosure relates to the field of semiconductor devices and power device applications. In particular, the disclosure relates to Gallium Nitride (GaN) Technology for Power Device Applications.

### BACKGROUND

A key step in GaN technology, used for example in power, radio frequency (RF) and LED applications, is represented by the proper activation of dopant elements in the device and, therefore, in the capability of forming n-type and p-type, highly doped regions and, finally, in the capability of forming p-n junctions. In wide bandgap technologies, like GaN, the formation of highly doped p-type regions is particularly tricky. The first reason is represented by the fact that the energy levels for acceptors is quite far from the valence band edge. For example, Magnesium, which is conventionally used for p-type doping in GaN, has an activation energy in the range of 170-200 meV. The second reason is represented by the complex formation of aggregates that forbids an efficient activation of the dopant. It is believed that a main mechanism is represented by the formation of Mg—H complexes. These complexes, forbids the magnesium to reach substitutional lattice sites. The efficient activation of dopants in deep trenches has a great relevance for all future vertical and semi-vertical Power MOSFET in GaN technology. Apart from the details of the process flow, a key ingredient for the successful implementation is that the p-type GaN layer inside the deep trench is fully activated, e.g. the dopant elements (Mg in this case) are properly activated.

### BRIEF DESCRIPTION OF THE DRAWINGS

Embodiments of the disclosure will be described with respect to the following figures, in which:

FIG. 1a shows a schematic cross section of a first embodiment of a semiconductor device 100 according to the disclosure;

FIG. 1b shows a schematic cross section of a second embodiment of a semiconductor device 100 according to the disclosure;

FIG. 1c shows a schematic cross section of a third embodiment of a semiconductor device 100 according to the disclosure; and

FIG. 2 shows three schematic top side views according to three further embodiments of a semiconductor device 100 according to the disclosure.

### DETAILED DESCRIPTION

This disclosure provides for an efficient activation of dopants in deep trenches.

In particular, the disclosure provides a semiconductor device, in particular in GaN technology, with highly doped n-type and p-type regions.

This disclosure presents a new technology that allows the efficient dopant activation of p-type material in GaN technology that is especially suited to be used in conjunction with deep trenches filled with doped material, where the conventional activation techniques is not sufficient to reach a satisfactory dopant activation. Advantages of the new technology presented hereinafter can be summarized as follows: it allows the efficient dopant activation in deep trenches; it can be combined with a source-connected p-type deep trench that connects the 2DHG (2-dimensional hole gas); it allows a minimization of the dynamic effects and current collapse phenomena that today can be a major concern for the successful development of GaN technology for RF and Power Applications. This new technology is also suited for the realization of vertical GaN Power Transistors, where buried and deep p-type doped regions are needed for the device operation.

In order to describe the disclosure in detail, the following terms, abbreviations and notations will be used:
GaN Gallium Nitride
RF radio frequency
MOSFET Metal Oxide Semiconductor Field Effect Transistor
2DHG 2-dimensional hole gas
2DEG 2-dimensional electron gas
UID unintentionally doped
HEMT high electron mobility transistor
RDSON on-resistance between Drain and Source terminals

In this disclosure, semiconductor devices in GaN technology are described. GaN Technology is currently developed as replacement for conventional Silicon technology for Power Electronic Applications. Polarization charges are one of the key ingredient of GaN technology that are exploited to achieve better performance than Silicon technology. A normally-off p-GaN HEMT can be represented by a silicon substrate used as base material and a nitride based epitaxial layer grown on top of the silicon substrate. This complex epitaxial layer may be composed by the following main layers: i) nucleation layer; ii) transition layer; iii) carbon-doped buffer layer; iv) unintentionally doped GaN channel layer; v) AlGaN barrier layer. In some special cases, the C-doped buffer and UID GaN layer can be modified by introducing small amount of Aluminum (<10%). This particular case is generally referred to as “back-barrier approach”.

In the back-barrier approach, due to the presence of the polarization charges, there is the formation of a 2DHG (two dimensional hole gas) at the interface between the GaN channel and the AlGaN buffer. Advantages of the AlGaN back-barrier can be summarized as follows: 1) Positive shift of the threshold voltage. Higher positive value of the threshold voltage can be achieved thanks to the presence of the back-barrier. 2) Reduction of the subthreshold leakage and, short channel effects, in general. 3) The presence of a two dimensional hole gas can have very beneficial effects on minimizing the dynamic effects in GaN technology (current collapse, dynamic RDSON). The main disadvantage of the back-barrier is that the 2DHG is effectively floating. Hole can then move left or right, depending on the applied field and can strongly impact the carrier density and the field distribution in the device. The present disclosure provides for avoiding or at least strongly reducing this floating of the 2DHG.

Embodiments of the disclosure describe a new technology that can alleviate the aforementioned issues. In these embodiments, a source connected pGaN layer can be used to connect the two-dimensional hole gas that forms at the bottom of the back-barrier, avoiding therefore that holes remain floating. A strong hole channel that is kept at the fixed source potential provides advantages in terms of dynamic effect optimization for GaN Technology for Power and RF applications. In particular, prior to the gate formation, a trench can be opened at the source side of the power device and filled with a p-type doped GaN layer during the following growth of the p-GaN layer needed for the gate module. Apart from the details of the process flow, a key ingredient for the successful implementation is that the p-type GaN layer inside the deep trench is fully activated, e.g. the dopant elements (Mg in this case) are properly activated via a dedicated process steps such as annealing, for example.

A key component for the successful activation of p-type dopants is the provisioning of one or more hollow chambers in the p-type doped region in order to form an escape path for Hydrogen atoms which are formed during a dopant activation of the p-type doped region during fabrication of the semiconductor device.

Successful activation of the Mg doping in GaN LEDs has allowed the fabrication and commercialization of the Blue LED. The efficient activation of dopants in deep trenches as presented in this disclosure has great relevance for all future vertical and semi-vertical Power MOSFET in GaN technology.

According to a first aspect, the disclosure relates to a semiconductor device, comprising: a semiconductor substrate; an Aluminum Gallium-Nitride, AlGaN, back-barrier layer formed above the semiconductor substrate; a GaN channel layer formed on the AlGaN back-barrier layer; wherein a two-dimensional hole gas, 2DHG, is formed at an interface between the GaN channel layer and the AlGaN back-barrier layer; a p-type doped region formed above the semiconductor substrate and next to the GaN channel layer and the AlGaN back-barrier layer, the p-type doped region having a top face and a bottom face opposing the top face, wherein the p-type doped region is configured to provide an Ohmic contact for the two-dimensional hole gas formed at the interface between the GaN channel layer and the AlGaN back-barrier layer; wherein the p-type doped region comprises Magnesium as a p-type dopant; wherein the p-type doped region comprises one or more hollow chambers extending from the top face of the p-type doped region, the one or more hollow chambers being configured to form an escape path for Hydrogen atoms which are formed during a dopant activation of the p-type doped region during fabrication of the semiconductor device.

Such a semiconductor device with hollow chambers provides a semiconductor device allowing efficient dopant activation, in particular in deep trenches. The device can be combined with a source-connected p-type deep trench that connects the 2DHG (2-dimensional hole gas). Such a GaN semiconductor device allows minimization of the dynamic effects and current collapse phenomena that are still today a major concern for the successful development of GaN technology for RF and Power Applications. This semiconductor device is also suited for the realization of vertical GaN Power Transistors, where buried and deep p-type doped regions are needed for the device operation.

The p-type doped region may alternatively comprise other dopants than Magnesium (Mg) or combination of Magnesium with other dopants. However, Mg is currently the most widely used element for p-type doping. Alternatively, Ca, Zn, Be may be used.

In an exemplary implementation of the semiconductor device, the one or more hollow chambers are filled with air or gas. Thus, an optimal escape path of the produced hydrogen can be provided, since hydrogen can use air or gas as an escape medium. From an electrical point of view, any dielectric material can be used, such as SiO2, high-k, etc. However, air allows H to escape easily.

In an exemplary implementation of the semiconductor device, the one or more hollow chambers are open to an environment of the semiconductor device. The escape path has a good connection to the environment in order to allow an optimal escape of the produced hydrogen. The chambers can be open to the atmosphere not only during fabrication of the semiconductor device. Alternatively, the chambers may be closed and configured to serve as an escape room or storage for the produced Hydrogen.

In an exemplary implementation of the semiconductor device, the dopant activation of the p-type doped region during fabrication of the semiconductor device comprises thermal annealing by which the Hydrogen atoms are released. By applying thermal annealing dopant activation can be efficiently enabled.

In an exemplary implementation of the semiconductor device, the dopant activation of the p-type doped region dissociates Magnesium-Hydrogen complexes formed in the p-type doped region in order to release the Hydrogen and electrically activate the Magnesium. By dissociation of the Magnesium-Hydrogen complexes, Magnesium can be efficiently released which can provide high doping regions. The semiconductor device may be a Gallium-Nitride (GaN) semiconductor device, for example. The p-type doped region 101 may form a p-type doped GaN region, for example.

In an exemplary implementation of the semiconductor device, an activation energy for the dopant activation of the p-type doped region is in a range between 160 meV and 200 meV. At this activation energy Magnesium can be efficiently released and thus high dopant regions can be provided in the semiconductor device.

In an exemplary implementation of the semiconductor device, the p-type doped region comprises one or more side faces formed between the top face and the bottom face of the p-type doped region; wherein at least one hollow chamber of the one or more hollow chambers is formed at the one or more side faces of the p-type doped region. Hollow chambers can be formed at the side faces of the p-type doped region; the side faces can be easily connected to the environment resulting in an efficient release of the produced hydrogen.

In an exemplary implementation of the semiconductor device, at least one hollow chamber of the one or more hollow chambers is formed in a center of the p-type doped region. The hollow chambers have a lot of contact areas with the p-type doped region resulting in an efficient release of hydrogen from the p-type doped region.

In an exemplary implementation of the semiconductor device, at least one hollow chamber of the one or more hollow chambers extends at least from the top face to the bottom face of the p-type doped region. The hollow chambers extend deep into the p-type doped region allowing an efficient transfer of hydrogen to the hollow chambers.

In an exemplary implementation of the semiconductor device, at least one hollow chamber of the one or more hollow chambers extends from the top face of the p-type doped region inside the p-type doped region. The hydrogen atoms can be efficiently released via the top face of the p-type doped region.

In one example, the one or more hollow chambers may reach the bottom face of the p-type doped region. In another example, the one or more hollow chambers may not reach the bottom face of the p-type doped region, in this case, the bottom of the hollow chambers may be formed by the p-type doped region.

In an exemplary implementation of the semiconductor device, the semiconductor device comprises: a top surface and a bottom surface opposing the top surface; a trench formed at the top surface of the semiconductor device, the trench being filled with p-type doped material, wherein the p-type doped material is forming the p-type doped region. Thus, dopant regions can be efficiently activated in trenches, in particular in deep trenches.

In an exemplary implementation of the semiconductor device, the semiconductor device comprises: a source electrode forming a source finger at the top surface of the semiconductor device, the source finger comprising two source finger sides and a center between the two source finger sides; wherein the one or more hollow chambers are formed along the source finger sides or along the source finger center. A large contact area can be provided between the hollow chambers and the source fingers which results in an efficient transfer of the hydrogen atoms into the environment.

In an exemplary implementation of the semiconductor device, the one or more hollow chambers are continuously or discontinuously formed along the two source finger sides or along the center of the source finger. This provides flexible design options.

In an exemplary implementation of the semiconductor device, the p-type doped region connects the 2DHG to a source electrode in order to avoid a floating of the 2DHG. Thus, floating of the 2DHG can be efficiently disabled.

The semiconductor device may comprise a transition layer formed at the semiconductor substrate. The AlGaN back-barrier layer can be formed on the transition layer. The semiconductor device may comprise an AlGaN barrier layer formed on the GaN channel layer. A two-dimensional electron gas, 2DEG, can be formed at an interface between the GaN channel layer and the AlGaN barrier layer. The semiconductor device may comprise a p-type doped GaN layer formed on the AlGaN barrier layer.

The p-type doped GaN layer can form a second p-type doped region of the semiconductor device. This second p-type doped region may comprise one or more other hollow chambers extending from a top face of the second p-type doped region into the second p-type doped region.

According to a second aspect, the disclosure relates to a method for producing a semiconductor device, the method comprising: forming a semiconductor substrate; forming an Aluminum Gallium-Nitride, AlGaN, back-barrier layer above the semiconductor substrate; forming a GaN channel layer on the AlGaN back-barrier layer; wherein a two-dimensional hole gas, 2DHG, is formed at an interface between the GaN channel layer and the AlGaN back-barrier layer; forming a p-type doped region above the semiconductor substrate and next to the GaN channel layer and the AlGaN back-barrier layer, the p-type doped region having a top face and a bottom face opposing the top face, wherein the p-type doped region provides an ohmic contact for the two-dimensional hole gas formed at the interface between the GaN channel layer and the AlGaN back-barrier layer; wherein the p-type doped region comprises Magnesium as a p-type dopant; forming one or more hollow chambers in the p-type doped region, the one or more hollow chambers extending from the top face of the p-type doped region; dopant activating the p-type doped region, the dopant activating resulting in formation of Hydrogen atoms; and releasing the Hydrogen atoms via the one or more hollow chambers.

Accordingly, a semiconductor device can be efficiently produced that allows efficient dopant activation, in particular in deep trenches. The method can be combined with production of a source-connected p-type deep trench that connects the 2DHG (2-dimensional hole gas). Such a production method allows minimization of the dynamic effects and current collapse phenomena that are still today a major concern for the successful development of GaN technology for RF and Power Applications. This method is also suited for the manufacturing of vertical GaN Power Transistors, where buried and deep p-type doped regions are needed for the device operation.

The p-type doped region may alternatively comprise other dopants than Magnesium or combination of Magnesium with other dopants.

In the following, reference is made to the accompanying drawings, which form a part thereof, and in which is shown by way of illustration specific aspects in which the disclosure may be practiced. It is understood that other aspects may be utilized and structural or logical changes may be made without departing from the scope of the disclosure. The following detailed description, therefore, is not to be taken in a limiting sense, and the scope of the disclosure is defined by the appended claims.

It is understood that comments made in connection with a described method may also hold true for a corresponding device or system configured to perform the method and vice versa. For example, if a specific method step is described, a corresponding device may include a unit to perform the described method step, even if such unit is not explicitly described or illustrated in the figures. Further, it is understood that the features of the various exemplary aspects described herein may be combined with each other, unless specifically noted otherwise.

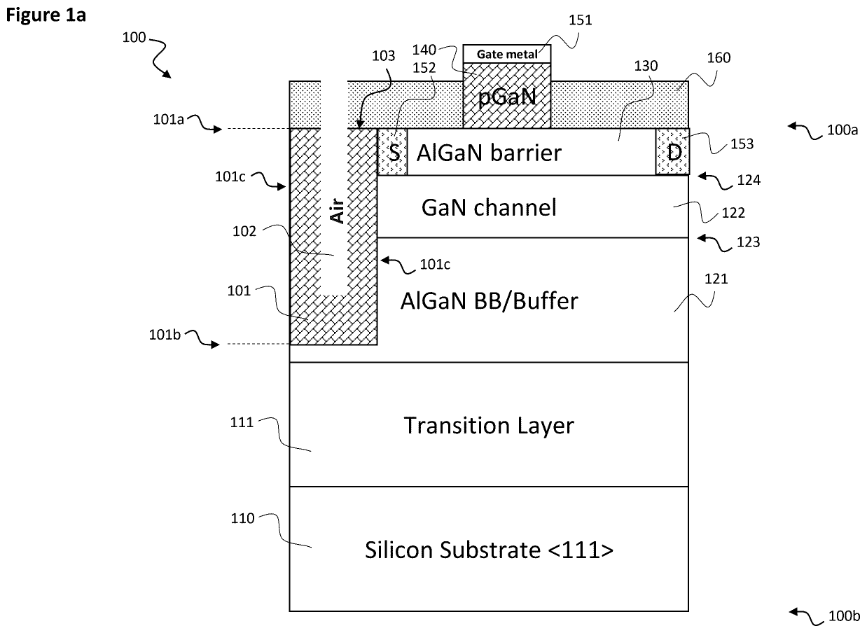

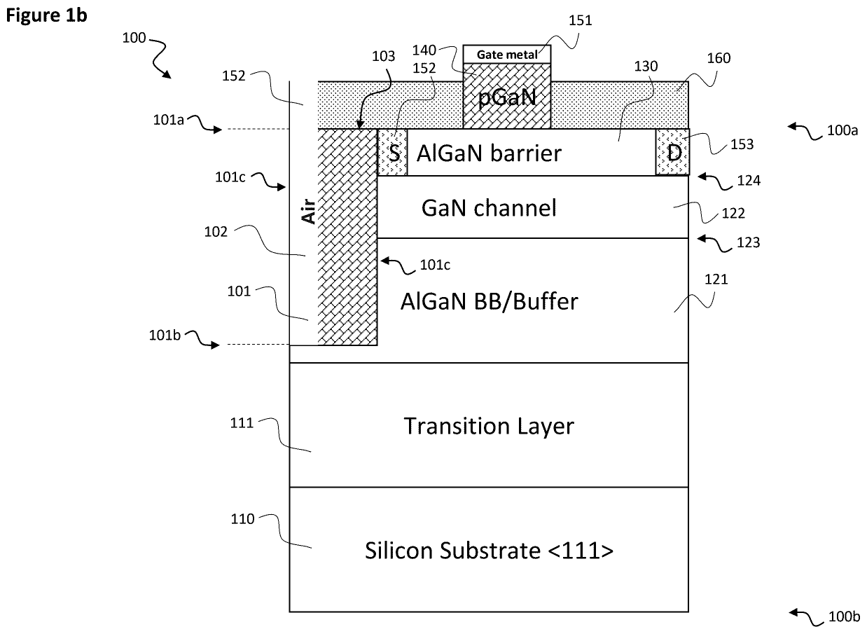

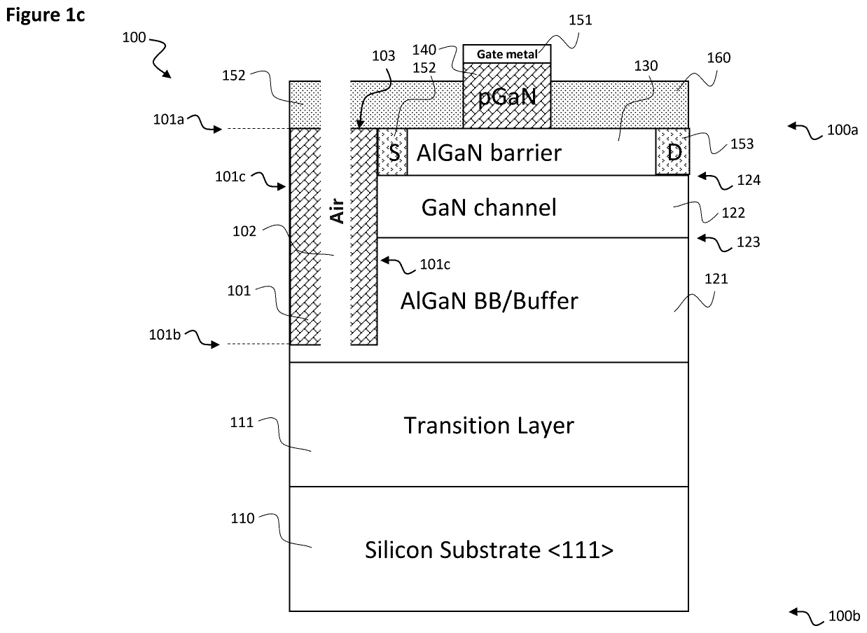

FIG. 1a shows a schematic cross section of a first embodiment of a semiconductor device 100 according to the disclosure.

As shown in FIG. 1a, a trench 103, in particular a deep trench 103, is created and filled, subsequently, with a p-type doped material, e.g., GaN doped with Magnesium. The main purpose of this doped region is to electrically contact the otherwise floating two-dimensional hole gas, which forms at the interface between the GaN channel and the Carbon doped buffer underneath.

Due to the limited dopant activation possible for p-type dopants in deep trenches, one or more hollow chambers 102, e.g., air-gaps, as schematically shown in FIG. 1a are introduced. These hollow chambers 102 or air-gaps can be formed on the side of the trench (e.g., left or right) or in the center of the trench 103. The main purpose of those openings is to create an escape path for the hydrogen atoms, so that during the annealing steps, and after the breakage of the Mg—H complexes, the hydrogen can escape and allow better dopant activation in the deep trenches.

The semiconductor device 100 illustrated in FIG. 1a comprises: a semiconductor substrate 110; an Aluminum Gallium-Nitride, AlGaN, back-barrier layer 121 formed above the semiconductor substrate 110; a GaN channel layer 122 formed on the AlGaN back-barrier layer 121; wherein a two-dimensional hole gas, 2DHG, is formed at an interface 123 between the GaN channel layer 122 and the AlGaN back-barrier layer 121; and a p-type doped region 101 which is formed above the semiconductor substrate 110 and next to the GaN channel layer 122 and the AlGaN back-barrier layer 121. The p-type doped region 101 has a top face 101a and a bottom face 101b opposing the top face 101a. The p-type doped region 101 is configured to provide an ohmic contact for the two-dimensional hole gas formed at the interface 123 between the GaN channel layer 122 and the AlGaN back-barrier layer 121.

The p-type doped region 101 may comprise Magnesium as a p-type dopant. The p-type doped region 101 may alternatively comprise other dopants than Magnesium (Mg) or combination of Magnesium with other dopants. However, Mg is the most widely used element for p-type doping. Alternatively, Ca, Zn, Be may be used.

As shown in FIG. 1a, the p-type doped region 101 comprises one or more hollow chambers 102 extending from the top face 101a of the p-type doped region 101.

The one or more hollow chambers 102 are configured to form an escape path for Hydrogen atoms which are formed during a dopant activation of the p-type doped region 101 during fabrication of the semiconductor device 100.

The one or more hollow chambers 102 may be filled with air or gas. From an electrical point of view, any dielectric material can be used, such as SiO2, high-k, etc. However, air allows H to escape easily.

The one or more hollow chambers 102 can be open to an environment of the semiconductor device 100. The chambers 102 can be open to the atmosphere not only during fabrication of the semiconductor device 100. Alternatively, the chambers 102 may be closed and configured to serve as an escape room or storage for the produced Hydrogen.

The dopant activation of the p-type doped region 101 during fabrication of the semiconductor device 100 may comprise thermal annealing by which the Hydrogen atoms are released.

The dopant activation of the p-type doped region 101 can dissociate Magnesium-Hydrogen complexes formed in the p-type doped region 101 in order to release the Hydrogen and electrically activate the Magnesium.

The semiconductor device 100 may be a Gallium-Nitride (GaN) semiconductor device, for example. The p-type doped region 101 may form a p-type doped GaN region, for example.

An activation energy for the dopant activation of the p-type doped region 101 may be in a range between 160 meV and 200 meV, for example. Other ranges can be used as well, for example between 150 meV and 210 meV or between 140 meV and 220 meV or between 110 meV and 250 meV or between 170 meV and 190 meV or between 165 meV and 195 meV as some other examples.

The p-type doped region 101 may comprise one or more side faces 101c formed between the top face 101a and the bottom face 101b of the p-type doped region 101 as shown in FIG. 1a. At least one hollow chamber of the one or more hollow chambers 102 may be formed at the one or more side faces 101c of the p-type doped region 101 as exemplarily illustrated in FIG. 1b.

At least one hollow chamber of the one or more hollow chambers 102 may be formed in a center of the p-type doped region 101 as shown in FIG. 1a.

In another embodiment, at least one hollow chamber of the one or more hollow chambers 102 may be formed at the one or more side faces 101c of the p-type doped region 101 and at least one hollow chamber of the one or more hollow chambers 102 may be formed in a center of the p-type doped region 101.

At least one hollow chamber of the one or more hollow chambers 102 may extend at least from the top face 101a to the bottom face 101b of the p-type doped region 101, e.g., as shown in FIGS. 1b and 1c.

At least one hollow chamber of the one or more hollow chambers 102 may extends from the top face 101a of the p-type doped region 101 inside the p-type doped region 101, e.g., as shown in FIGS. 1a, 1b, 1c.

In one example, the one or more hollow chambers 102 may reach the bottom face 101b of the p-type doped region 101. In another example, the one or more hollow chambers 102 may not reach the bottom face 101b of the p-type doped region 101, in this case, the bottom of the hollow chambers 102 may be formed by the p-type doped region 101.

The semiconductor device 100 may comprise: a top surface 100a and a bottom surface 100b opposing the top surface 100a; and a trench 103 formed at the top surface 100a of the semiconductor device 100. The trench 103 may be filled with p-type doped material as shown in FIGS. 1a, 1b and 1c. The p-type doped material is forming the p-type doped region 101.

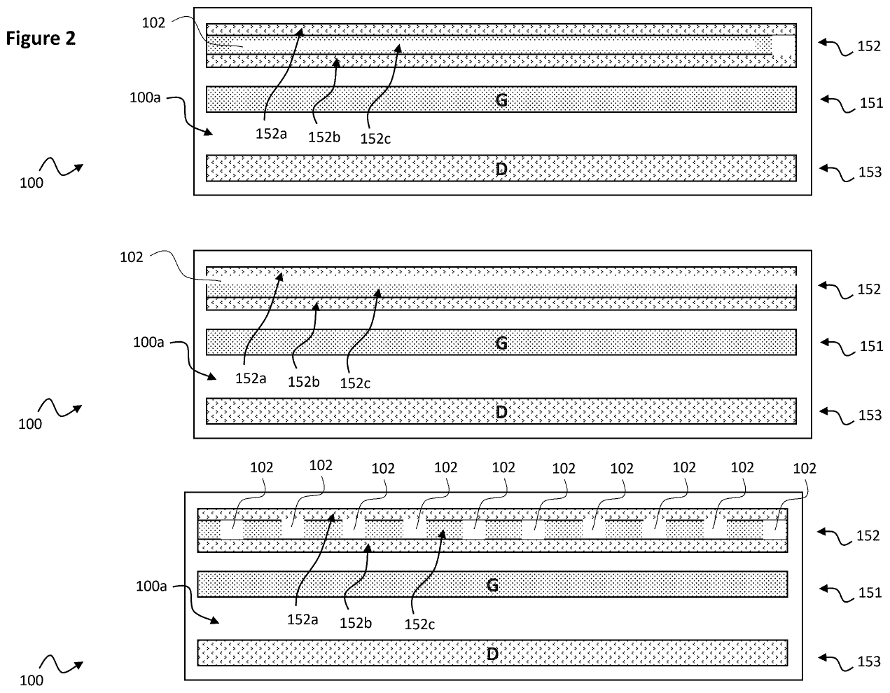

The semiconductor device 100 may comprise: a source electrode 152 forming a source finger at the top surface 100a of the semiconductor device 100, e.g., as shown in FIG. 2. The source finger may comprise two source finger sides 152a, 152b and a center 152c between the two source finger sides 152a, 152b, e.g., as shown in FIG. 2. The one or more hollow chambers 102 may be formed along the source finger sides 152a, 152b or along the source finger center 152c, e.g., as shown in FIG. 2.

The one or more hollow chambers 102 can be continuously or discontinuously formed along the two source finger sides 152a, 152b or along the center 152c of the source finger, e.g., as shown in FIG. 2.

The p-type doped region 101 may connect the 2DHG to a source electrode 152 in order to avoid a floating of the 2DHG.

As shown in FIG. 1a, the semiconductor device 100 may comprise a transition layer 111 formed at the semiconductor substrate 110. The AlGaN back-barrier layer 121 can be formed on the transition layer 111.

The semiconductor device 100 may comprise an AlGaN barrier layer 130 formed on the GaN channel layer 122. A two-dimensional electron gas, 2DEG, can be formed at an interface 124 between the GaN channel layer 122 and the AlGaN barrier layer 130 as shown in FIG. 1a.

A first ohmic contact 152 for the two-dimensional electron gas can be used as Source contact and a second ohmic contact 153 for the two-dimensional electron gas can be used as Drain contact. A passivation layer 160 may cover the p-type doped region 101, the AlGaN barrier layer 130 and the two ohmic contacts 152, 153 at the top surface 100a of the semiconductor device 100. The hollow chambers 102 may extend through the passivation layer 160. The passivation layer 160 may be a high-k dielectric, for example made of Silicon Nitride (SiN), Aluminum Nitride (AlN), Silicon Oxide (SiO₂), or any combination thereof.

The semiconductor device 100 may comprise a p-type doped GaN layer 140 formed on the AlGaN barrier layer 130 as shown in FIG. 1a. The p-type doped GaN layer 140 can form a second p-type doped region of the semiconductor device 100. This second p-type doped region may comprise one or more other hollow chambers 102 extending from a top face of the second p-type doped region into the second p-type doped region (not shown in FIG. 1a). The p-type doped GaN layer 140 may extend through the passivation layer 160. A gate metal 151 can be placed on top of the p-type doped GaN layer 140.

FIG. 1b shows a schematic cross section of a second embodiment of a semiconductor device 100 according to the disclosure.

The structure of the semiconductor device 100 shown in FIG. 1b is the same as for the semiconductor device 100 described above with respect to FIG. 1a. One difference of the second embodiment over the first embodiment is that the hollow chambers 102 are not placed in the center of the p-type doped region 101 but at the sidewall 101c of that region 101.

Another difference of the second embodiment over the first embodiment is that the at least one hollow chamber 102 extends from the top face 101a of the p-type doped region 101 down to the bottom face 101b of the p-type doped region 101. In this case, the bottom of the at least one hollow chamber 102 may be formed by the AlGaN back-barrier layer 121.

FIG. 1c shows a schematic cross section of a third embodiment of a semiconductor device 100 according to the disclosure.

The structure of the semiconductor device 100 shown in FIG. 1c is the same as for the semiconductor device 100 described above with respect to FIG. 1a. One difference of the third embodiment over the first embodiment is that the at least one hollow chamber 102 extends from the top face 101a of the p-type doped region 101 to the bottom face 101b of the p-type doped region 101 and down to the AlGaN back-barrier layer 121. In this case, the bottom and depending on the depth of the at least one hollow chamber 102, also the lower parts of the side walls of the at least one hollow chamber 102 may be formed by the AlGaN back-barrier layer 121.

FIG. 2 shows three schematic top side views according to three further embodiments of a semiconductor device 100 according to the disclosure.

The structure of the semiconductor device 100 shown in FIG. 2 is the same as for the semiconductor device 100 described above with respect to FIG. 1a. In these three top side views different structures of the hollow chambers 102 are shown.

The semiconductor device 100 may comprise a source electrode 152, a gate electrode 151 and a drain electrode 153. The source electrode 152 may be shaped differently as shown in the three embodiments of FIG. 2.

The source electrode 152 may form a source finger at the top surface 100a of the semiconductor device 100. The source finger may comprise two source finger sides 152a, 152b and a center 152c between the two source finger sides 152a, 152b as shown in FIG. 2.

The one or more hollow chambers 102 may be formed along the source finger sides 152a, 152b or along the source finger center 152c as shown in FIG. 2.

The one or more hollow chambers 102 can be continuously or discontinuously formed along the two source finger sides 152a, 152b or along the center 152c of the source finger. The upper and middle pictures in FIG. 2 illustrate continuously formed hollow chambers 102 while the bottom picture in FIG. 2 illustrates discontinuously formed hollow chambers 102. In this embodiment, the hollow chambers 102 may form a regular pattern. It understands that also an irregular pattern may be formed by the hollow chambers or even a random pattern.

As already mentioned above, the hollow chambers 102 may be introduced along the source finger sides 152a, 152b or along the source finger center 152c. The hollow chambers 102 can be continuous or also discontinuous, e.g. interrupted, for example as a series combination of more than one single hollow chamber 102.

The disclosure also presents a method for producing a semiconductor device 100 as shown in FIGS. 1a, 1b, 1c and 2.

Such a method comprises the following:
Forming a semiconductor substrate 110;
Forming an Aluminum Gallium-Nitride, AlGaN, back-barrier layer 121 above the semiconductor substrate 110;
Forming a GaN channel layer (122) on the AlGaN back-barrier layer 121; wherein a two-dimensional hole gas, 2DHG, is formed at an interface 123 between the GaN channel layer 122 and the AlGaN back-barrier layer 121, e.g, as described above with respect to FIG. 1a;
Forming a p-type doped region 101 above the semiconductor substrate 110 and next to the GaN channel layer 122 and the AlGaN back-barrier layer 121, the p-type doped region having a top face 101a and a bottom face 101b opposing the top face 101a, wherein the p-type doped region 101 provides an ohmic contact for the two-dimensional hole gas formed at the interface between the GaN channel layer 122 and the AlGaN back-barrier layer 121; wherein the p-type doped region 101 may comprise Magnesium as a p-type dopant, e.g, as described above with respect to FIG. 1a;
Forming one or more hollow chambers 102 in the p-type doped region 101, the one or more hollow chambers 102 extending from the top face 101a of the p-type doped region 101, e.g, as described above with respect to FIG. 1a;
Dopant activating the p-type doped region 101, the dopant activating resulting in formation of Hydrogen atoms; and
Releasing the Hydrogen atoms via the one or more hollow chambers 102, e.g, as described above with respect to FIG. 1a.

The p-type doped region 101 may alternatively comprise other dopants than Magnesium or combination of Magnesium with other dopants.

While a particular feature or aspect of the disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Also, the terms “exemplary”, “for example” and “e.g.” are merely meant as an example, rather than the best or optimal. The terms “coupled” and “connected”, along with derivatives may have been used. It should be understood that these terms may have been used to indicate that two elements cooperate or interact with each other regardless whether they are in direct physical or electrical contact, or they are not in direct contact with each other.

Although specific aspects have been illustrated and described herein, it will be appreciated by those of ordinary skill in the art that a variety of alternate and/or equivalent implementations may be substituted for the specific aspects shown and described without departing from the scope of the disclosure. This application is intended to cover any adaptations or variations of the specific aspects discussed herein.

Although the elements in the following claims are recited in a particular sequence with corresponding labeling, unless the claim recitations otherwise imply a particular sequence for implementing some or all of those elements, those elements are not necessarily intended to be limited to being implemented in that particular sequence.

Many alternatives, modifications, and variations will be apparent to those skilled in the art in light of the above teachings. Of course, those skilled in the art readily recognize that there are numerous applications of the disclosure beyond those described herein. While the disclosure has been described with reference to one or more particular embodiments, those skilled in the art recognize that many changes may be made thereto without departing from the scope of the disclosure. It is therefore to be understood that within the scope of the appended claims and their equivalents, the disclosure may be practiced otherwise than as specifically described herein.

What is claimed is:

1. A semiconductor device, comprising:
a semiconductor substrate;
an Aluminum Gallium-Nitride (AlGaN) back-barrier layer formed above the semiconductor substrate;
a Gallium-Nitride (GaN) channel layer formed on the AlGaN back-barrier layer; and
a p-type doped region formed above the semiconductor substrate and next to the GaN channel layer and the AlGaN back-barrier layer, the p-type doped region having a top face and a bottom face opposing the top face, wherein the p-type doped region is configured to provide an ohmic contact for a two-dimensional hole gas (2DHG) formed at an interface between the GaN channel layer and the AlGaN back-barrier layer;
wherein the p-type doped region comprises Magnesium as a p-type dopant;
wherein the p-type doped region comprises one or more hollow chambers extending from the top face of the p-type doped region, and
wherein the one or more hollow chambers are configured to form an escape path for Hydrogen atoms which are formed during a dopant activation of the p-type doped region during fabrication of the semiconductor device.

2. The semiconductor device of claim 1, wherein the one or more hollow chambers are filled with air or gas.

3. The semiconductor device of claim 1, wherein the one or more hollow chambers are open to an environment of the semiconductor device.

4. The semiconductor device of claim 1, wherein the dopant activation of the p-type doped region during fabrication of the semiconductor device comprises thermal annealing by which the Hydrogen atoms are released.

5. The semiconductor device of claim 1, wherein the dopant activation of the p-type doped region dissociates Magnesium-Hydrogen complexes formed in the p-type doped region in order to release the Hydrogen and electrically activate the Magnesium.

6. The semiconductor device of claim 1, wherein an activation energy for the dopant activation of the p-type doped region is in a range of 160 meV to 200 meV.

7. The semiconductor device of claim 1, wherein the p-type doped region comprises one or more side faces formed between the top face and the bottom face of the p-type doped region;
wherein at least one hollow chamber of the one or more hollow chambers is formed at the one or more side faces of the p-type doped region.

8. The semiconductor device of claim 1, wherein at least one hollow chamber of the one or more hollow chambers is formed in a center of the p-type doped region.

9. The semiconductor device of claim 1, wherein at least one hollow chamber of the one or more hollow chambers extends at least from the top face to the bottom face of the p-type doped region.

10. The semiconductor device of claim 1, wherein at least one hollow chamber of the one or more hollow chambers extends from the top face of the p-type doped region inside the p-type doped region.

11. The semiconductor device of claim 1, further comprising:
a top surface and a bottom surface opposing the top surface; and
a trench formed at the top surface of the semiconductor device, the trench being filled with p-type doped material,
wherein the p-type doped material is forming the p-type doped region.

12. The semiconductor device of claim 11, further comprising:
a source electrode forming a source finger at the top surface of the semiconductor device, the source finger comprising two source finger sides and a center between the two source finger sides;
wherein the one or more hollow chambers are formed along the source finger sides or along a source finger center.

13. The semiconductor device of claim 12, wherein the one or more hollow chambers are continuously or discontinuously formed along the two source finger sides or along the center of the source finger.

14. The semiconductor device of claim 1, wherein the p-type doped region connects the 2DHG to a source electrode in order to avoid a floating of the 2DHG.

15. A method for producing a semiconductor device, the method comprising:
forming a semiconductor substrate;
forming an Aluminum Gallium-Nitride (AlGaN) back-barrier layer above the semiconductor substrate;
forming a Gallium-Nitride (GaN) channel layer on the AlGaN back-barrier layer;
forming a two-dimensional hole gas (2DHG) at an interface between the GaN channel layer and the AlGaN back-barrier layer;
forming a p-type doped region above the semiconductor substrate and next to the GaN channel layer and the AlGaN back-barrier layer, the p-type doped region having a top face and a bottom face opposing the top face, wherein the p-type doped region provides an ohmic contact for the 2DHG, and wherein the p-type doped region comprises Magnesium as a p-type dopant;
forming one or more hollow chambers in the p-type doped region, the one or more hollow chambers extending from the top face of the p-type doped region;
dopant activating the p-type doped region, the dopant activating resulting in formation of Hydrogen atoms; and
releasing the Hydrogen atoms via the one or more hollow chambers.
